(19) United States
(12) Patent Application Publication
(10) Pub. No.: US 2026/0177910 A1
(43) Pub. Date: Jun. 25, 2026

(54) PHOTOSENSITIVE MEDIA WITH DILUENT/SOLVENT MICROCAPSULES AND PHOTOSENSITIVE BLACK MICROCAPSULES IN UNDER-LAYER

(71) Applicant: Polaroid IP B.V., Enschede (NL)

(72) Inventors: Wei YOU, Taichung City (TW); Cheng-Hsuan WU, New Taipei City (TW); Rong-Chang LIANG, Cupertino, CA (US)

(21) Appl. No.: 19/000,402

(22) Filed: Dec. 23, 2024

(51) Int. Cl. G03F 7/00; G03F 7/09

(52) U.S. Cl. CPC G03F 7/002; G03F 7/094

(57) ABSTRACT

Imaging systems, microcapsules and method are provided, including an under-layer including one or more pressure-sensitive microcapsules including a solvent, plasticizer, or a diluent and/or a photo-hardenable black microcapsule including a black leuco-dye or a leuco-dye system. The resulting imaging sheets achieve improved image color saturation, an improved rate of image development, and enhanced dye mixing.

### FIELD

The present technology generally relates to systems, media, and methods used for processing articles, and more particularly to the systems, media, and methods for improving imaging media with diluent/solvent microcapsules and photosensitive black microcapsules in under-layer.

### BACKGROUND

The following discussion is provided to aid the reader in understanding the disclosure and is not admitted to describe or include prior art thereto.

Single-sheet, self-containing, full-color microcapsule imaging systems (e.g., Cycolor) comprising microcapsules encapsulated therein a photo-hardenable or photo-softenable composition and a leuco-dye as the internal phase have been known for years. For example, the photo-hardenable microcapsules are image-wise hardened by actinic radiation, and upon passing the exposed imaging sheet through a pressure roller, the microcapsules may be image-wise ruptured to release the internal phase. The leuco dyes thus released migrate to a developer material and react to form a full-color image with its color density (or grayscale) modulated by the exposure energy (time or pulse width), intensity (pulse amplitude), and/or pulse frequency.

To develop high quality, continuous-tone full-color images with a high color saturation, a high temperature post-heating/calendering step is often needed after the capsules are ruptured to (1) facilitate the leuco-dyes/developer reaction, (2) increase the degree of mixing of for example, the cyan, magenta and yellow leuco-dyes released from the unexposed and partially exposed red-, green- and blue-sensitive microcapsules, respectively, and (3) reduce the haze and improve the color reflectivity of the image layer. However, the requirements of low power consumption, light weight, and small footprint in many, if not all, of the battery-operated portable applications severely limit the use of high temperature and pressure in the printing process. An energy-saving and low-pressure solution is needed to address these issues.

The use of a non-photo-polymerizable reactive epoxidized diluent/plasticizer either in the photosensitive leuco-dye microcapsules or in a separate non-photosensitive microcapsule is described in US Publication No. 2023/0393459A1 to facilitate the development of the leuco-dyes and the mixing of the dyes. Improvements in the color saturation as well as the low temperature exposure latitude of the microcapsule imaging system were reported. The degree of discoloration or yellowness in the Dₘᵢₙ (minimum color density) areas was also reduced, which may be due to the reaction of the epoxy group of the diluent with the phenol group of the dye developer. US Publication No. 2023/0393460 to the same Applicant discloses a primer layer comprising a polymeric hollow particle and a white particulate having improved image color saturation and reduced printing power consumption. The entire contents of these applications are incorporated herein by reference in their entireties, including for the primers, microcapsules, and microcapsule imaging sheets disclosed therein.

Although the image quality was improved by the measures disclosed in the above-mentioned patent applications, the image color saturation, rate of image development and the degree of dye mixing, particularly in the low color density areas still require further improvements to meet the needs of high-quality, portable applications. The present technology is directed to overcoming these and other deficiencies.

### SUMMARY

In one aspect, which may be combined with any other aspect or embodiment, the present disclosure relates to an imaging system comprising: an under-layer comprising one or more pressure-sensitive microcapsules, said one or more pressure-sensitive microcapsules comprising a solvent, plasticizer, or diluent; an imaging layer overlying the under-layer and comprising one or more photosensitive microcapsules; said one or more photosensitive microcapsules comprising a leuco-dye and a multifunctional photo-polymerizable or photocrosslinkable monomer or oligomer; and a leuco-dye developer.

In some embodiments, the under-layer is a primer layer. In some embodiments, the under-layer is an adhesive layer or tie layer. In some embodiments, the under-layer is overlaid on to one surface of a first substrate. In some embodiments, the leuco dye developer is present in the same layer as the imaging layer. In some embodiments, the leuco-dye developer is present in a different layer from the imaging layer. In some embodiments, the imaging system further includes a second substrate with the photosensitive imaging layer and/or the leuco-dye developer layer deposited thereon.

In some embodiments, the one or more photosensitive microcapsules is photo-hardenable, photo-crosslinkable, or photo-polymerizable. In some embodiments, the one or more pressure-sensitive microcapsules comprising the solvent, plasticizer, or diluent is non-photosensitive. In some embodiments, the one or more pressure-sensitive microcapsules comprising the solvent, plasticizer or diluent is photosensitive. In some embodiments, the solvent, plasticizer, or diluent has a boiling point greater than 150° C. In some embodiments, the solvent or diluent has a boiling point greater than 200° C. In some embodiments, the solvent or diluent has a viscosity less than 600 cps. In some embodiments, the solvent or diluent has a viscosity less than 150 cps.

In some embodiments, the solvent, plasticizer, or diluent is selected from the group consisting of vegetable oils, adipates, phthalates, dihydroxyalkanes, alkyl phosphates, ethers or esters of ethylene glycol, propylene glycol, glycerol, trimethylol propane, pentaerythritol, and their epoxidized derivatives, or a combination of any two of more thereof. In some embodiments, the leuco-dye developer is selected from the group consisting of Lewis acids, acid clay, phenolic resins, novolac resins, salicylic acid, oxalic acid, phthalic acid, and their derivatives, metal complexes, copolymers, blends, or composites. In some embodiments, the leuco-dye developer is a zincated derivative.

In one aspect, which may be combined with any other aspect or embodiment, the present disclosure relates to an imaging system, comprising: a) an under-layer comprising one or more photo-hardenable black microcapsules, said one or more photo-hardenable black microcapsules comprising a photo-polymerizable or photo-crosslinkable multifunctional monomer or oligomer and a black leuco-dye or a leuco-dye system; and b) an imaging layer overlying the under-layer and comprising one or more photosensitive microcapsules; said photosensitive microcapsules comprising a leuco-dye and a multifunctional photo-polymerizable or crosslinkable monomer or oligomer.

In some embodiments, the leuco-dye system comprises a mixture of two or more leuco-dyes. In some embodiments, the two or more leuco-dyes are selected from a black leuco-dye, a cyan leuco-dye, a magenta leuco-dye, a yellow leuco-dye, a red leuco-dye, a green leuco-dye, and a blue-leuco dye. In some embodiments, the under-layer further comprises one or more pressure-sensitive microcapsules comprising a solvent, plasticizer, or a diluent for the leuco-dyes. In some embodiments, the photo-hardenable black microcapsule comprises a photoinitiator, a multifunctional acrylate monomer, and a black leuco-dye or a leuco-dye system.

In some embodiments, the spectral sensitivity of the photo-hardenable black microcapsule of the under-layer is different from that of the photosensitive microcapsule imaging layer. In some embodiments, the photo-hardenable black microcapsule of the under-layer is sensitive to a wavelength differing from at least one of a plurality of wavelengths used to expose the photosensitive microcapsules in the imaging layer. In some embodiments, the photo-hardenable black microcapsule is sensitive to a wavelength differing from each of a plurality of wavelengths used to expose the photosensitive microcapsules in the imaging layer. In some embodiments, the photo-hardenable black capsule is sensitive to white light, ultra-violet (UV), infra-red (IR), near infra-red, or yellow light.

In one aspect, which may be combined with any other aspect or embodiment, the present disclosure relates to an imaging system, comprising: a) a first substrate having two sides; b) an under-layer overlaying one side of the first substrate and comprising one or more microcapsules; c) an imaging layer overlying the under-layer and comprising one or more photosensitive microcapsules; said photosensitive microcapsule comprising a leuco-dye, a multifunctional photo-polymerizable or photocrosslinkable monomer or oligomer; and d) a leuco-dye developer layer overlaying the photosensitive microcapsule imaging layer. In some embodiments, the one or more microcapsules in the under-layer comprises: a solvent, plasticizer, or a diluent for the leuco-dye in the photosensitive microcapsule or the leuco-dye developer; and/or a multifunctional photo-polymerizable or cross-linkable monomer or oligomer, and a black leuco-dye or a leuco-dye system.

In some embodiments, the photosensitive microcapsule imaging layer and the leuco-dye developer layer are pre-mixed and overlayed as a single layer on the under-layer. In some embodiments, the imaging system further comprises a second substrate overlaying the developer layer or the imaging layer. In some embodiments, the developer layer comprises two layers: (a) a low-haze clear developer layer (Dc); and (b) a microporous translucent developer layer (Dp).

In some embodiments, to form a single-sheet imaging system, a developer sheet comprising a developer or layers on a second substrate is laminated with an imaging sheet comprising an imaging layer and an under-layer disposed on a first substrate. In some embodiments, to form a single-sheet imaging system, an under-layer sheet comprising an under-layer on a second substrate is laminated with an imaging sheet comprising an imaging layer and a developer layer or layers disposed on a first substrate. In some embodiments, to form a single-sheet imaging system, an optically clear, durable layer is disposed on an imaging sheet comprising a developer layer or layers, an imaging layer, and an under-layer disposed on a first substrate.

In some embodiments, the multifunctional photo-polymerizable monomer or oligomer in the photosensitive microcapsules is selected from the group consisting of multifunctional acrylates and methacrylates, multifunctional allyls or vinylbenzenes, and their oligomers, dendrimers, or blends. In some embodiments, the multifunctional photo-polymerizable monomer or oligomer in the photosensitive microcapsules is selected from the group consisting of multifunctional acrylates, and their oligomers, dendrimers or blends thereof. In some embodiments, the multifunctional acrylate is selected from the group consisting of pentaerythritol triacrylate (PETA-3), pentaerythritol tetra-acrylate (PETA-4), dipentaerythritol hexaacrylate (DPHA), dipentaerythritol pentaacrylate (DPPA), trimethylolpropane triacrylate (TMPTA), 1,6-hexanediol diacrylate (HDDA), tripropylene glycol diacrylate (TPGDA), and neopentyl glycol diacrylate (NPGDA). In some embodiments, the diluent comprises an epoxide compound. In some embodiments, the epoxide compound comprises two or more epoxide moieties. In some embodiments, the diluent comprises a di-epoxide or tri-epoxide compound. In some embodiments, the epoxide compound comprises at least one selected from the group consisting of triglycidyl trimethylolpropane (TMPTGE); epoxided oils including epoxided soybean oil; epoxided castor oil; epoxided linseed oil; dicyclopentadiene diepoxide; cycloaliphatic diepoxide; 3,4-epoxycyclohexylmethyl-3,4-epoxycyclohexanecarboxylate; and 1,2-cyclohexane dicarboxylic acid diglycidyl ester.

These and other features, together with the organization and manner of operation thereof, will become apparent from the following detailed description when taken in conjunction with the accompanying drawings.

### BRIEF DESCRIPTION OF THE DRAWINGS

The details of one or more embodiments are set forth in the accompanying drawings and the description below. Other features, aspects, and advantages of the disclosure will become apparent from the description, the drawings, and the claims. In the drawings, like reference numerals are used throughout the various views to designate like components.

FIG. 1 is a schematic illustration of an embodiment of an imaging sheet having photosensitive microcapsules including a leuco dye and pressure-sensitive microcapsules diluent comprising a solvent, plasticizer, or diluent, according to one embodiment of the present disclosure.

It will be recognized that some or all of the figures are schematic representations for purposes of illustration. The figures are provided for the purpose of illustrating one or more embodiments with the explicit understanding that they will not be used to limit the scope or the meaning of the claims. The depiction of a particular height, length, width, relative sizing, number of chambers, sub-chambers, and the like, are intended to serve as examples only, and are not intended to limit the scope of the present technology.

### DETAILED DESCRIPTION

Various embodiments are described hereinafter. It should be noted that the specific embodiments are not intended as an exhaustive description or as a limitation to the broader aspects discussed herein. One aspect described in conjunction with a particular embodiment is not necessarily limited to that embodiment and can be practiced with any other embodiment(s).

Features may be described herein as part of the same or separate aspects or embodiments of the present technology for the purpose of clarity and a concise description. It will be appreciated by the skilled person that the scope of the present technology may include embodiments having combinations of all or some of the features described herein as part of the same or separate embodiments.

Various techniques and mechanisms of the present technology will sometimes be described in singular form for clarity. However, it should be noted that some embodiments include multiple iterations of a technique or multiple instantiations of a mechanism unless noted otherwise. In the following description, numerous specific details are set forth in order to provide a thorough understanding of the present technology. Particular example embodiments of the present technology may be implemented without some or all of these specific details. In other instances, well known process operations have not been described in detail.

The following terms are used throughout and are as defined below.

As used herein and in the appended claims, singular articles such as “a” and “an” and “the” and similar referents in the context of describing the elements (especially in the context of the following claims) are to be construed to cover both the singular and the plural, unless otherwise indicated herein or clearly contradicted by context. Recitation of ranges of values herein are merely intended to serve as a shorthand method of refereeing individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the embodiments, and does not pose a limitation on the scope of the claims unless otherwise stated. No language in the specification should be construed as indicating any non-claimed element as essential.

The embodiments, illustratively described herein may suitably be practiced in the absence of any element or elements, limitation or limitations, not specifically disclosed herein. Thus, for example, the terms “comprising,” “including,” “containing,” etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the claimed technology. Additionally, the phrase “consisting essentially of” will be understood to include those elements specifically recited and those additional elements that do not materially affect the basic and novel characteristics of the claimed technology. The phrase “consisting of” excludes any element not specified. The expression “comprising” means “including, but not limited to.” Thus, other non-mentioned substances, additives, carriers, or steps may be present. Unless otherwise specified, “a” or “an” means one or more.

Unless otherwise indicated, all numbers expressing quantities of properties, parameters, conditions, and so forth, used in the specification and claims are to be understood as being modified in all instances by the term “about.” Accordingly, unless indicated to the contrary, the numerical parameters set forth in the following specification and attached claims are approximations. Any numerical parameter should at least be construed in light of the number reported significant digits and by applying ordinary rounding techniques. The term “about” when used before a numerical designation, e.g., temperature, time, amount, and concentration including range, indicates approximations which may vary by (+) or (−) 10%, 5% or 1%.

As will be understood by one of skill in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above. Finally, as will be understood by one skilled in the art, a range includes each individual member.

Various embodiments of the present technology described herein relates to systems, apparatus, media, and methods for photosensitive media applications. In one aspect, the present technology provides an improved photosensitive microcapsule imaging system. The imaging system may include an under-layer comprising one or more pressure-sensitive microcapsules. The one or more pressure-sensitive microcapsules may include a solvent, plasticizer, or diluent. The imaging system may also include an imaging layer overlying the under-layer and including one or more photosensitive microcapsules. The one or more photosensitive microcapsules may include a leuco-dye and a multifunctional photo-polymerizable or photocrosslinkable monomer or oligomer. The imaging system may further include a leuco-dye developer. The solvent or a diluent in the pressure-sensitive microcapsule may be a solvent or a diluent for the leuco-dye in the one or more photosensitive microcapsules, or a plasticizer for the developer.

In another aspect, the improved photosensitive microcapsule imaging system may include an under-layer which includes one or more photo-hardenable black microcapsules. The one or more photo-hardenable black microcapsules may include a photo-polymerizable or photo-crosslinkable multifunctional monomer or oligomer and a black leuco-dye or a leuco-dye system. The imaging system may also include an imaging layer overlying the under-layer and including photosensitive microcapsules. The photosensitive microcapsules may include a leuco-dye and a multifunctional photo-polymerizable or crosslinkable monomer or oligomer.

In one aspect, the present technology provides improved imaging media which includes one or more pressure-sensitive microcapsules and one or more photosensitive black microcapsules in under-layer. The one or more pressure-sensitive microcapsules may include a solvent, plasticizer, or diluent. The one or more photosensitive black microcapsules may include photo-hardenable black microcapsules. The one or more photo-hardenable black microcapsules may include a photo-polymerizable or photo-crosslinkable multifunctional monomer or oligomer, a photoinitiator, and a black leuco-dye or a leuco-dye system.

Depending on the type and desired effect, the various microcapsules disclosed herein may be non-photosensitive, that is, the core is neither softened nor hardened by actinic irradiation, or they may be photosensitive, in which the core is either softened or hardened by actinic irradiation. Additionally, or alternatively, the microcapsules can be pressure-sensitive, that is, when pressure is applied, it crushes the microcapsules, releasing the material inside, e.g., for microcapsules containing a leuco dye and/or a diluent, application of pressure releasing the dye and/or a diluent. The dye solution then can react with a developer to develop a visible color for application. The microcapsules can also be photo-hardenable, photo-crosslinkable, or photo-polymerizable, which means they can be hardened, crosslinked, or polymerized upon exposure to radiation and the materials encapsulated therein become non-release-able by pressure.

In another aspect, the present technology provides an imaging system comprising a) a first substrate having two sides; b) an under-layer overlaying one side of the first substrate and comprising one or more microcapsules; c) an imaging layer overlying the under-layer and comprising one or more photosensitive microcapsules; said photosensitive microcapsule comprising a photoinitiator, a leuco-dye, a multifunctional photopolymerizable or photocrosslinkable monomer or oligomer; and d) a leuco-dye developer layer overlaying the photosensitive microcapsule imaging layer. In some embodiments, the one or more microcapsules in the under-layer comprises: a solvent, plasticizer, or a diluent for the leuco-dye in the photosensitive microcapsule in the imaging layer or the leuco-dye developer. In some embodiments, the one or more microcapsules in the under-layer comprises a photoinitiator, a multifunctional photopolymerizable or cross-linkable monomer or oligomer, and a black leuco-dye or leuco-dye system. In some embodiments, the under-layer comprises one or more microcapsules of solvent, plasticizer, or diluent, and one or more photohardenable microcapsules comprising a photoinitiator, a multifunctional photopolymerizable or cross-linkable monomer or oligomer, and a black leuco-dye or leuco-dye system.

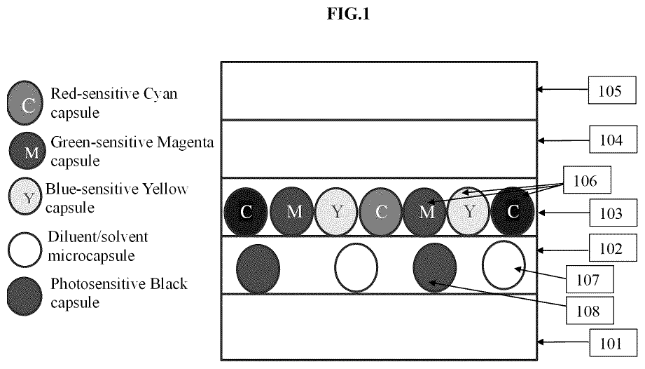

Referring to FIG. 1, in some embodiments, a microcapsule imaging system 100 according to the present disclosure includes an imaging layer 103, comprising microcapsules 106 (e.g., photosensitive microcapsules), disposed on a first substrate 101, which may optionally include a under-layer 102 in contact with the first substrate and/or the imaging layer 103. The imaging layer may further be in contact with a developer layer 104, which is a disposed on a second substrate 105 (e.g., transparent substrate). The under-layer may comprise pressure-sensitive microcapsules 107 comprising a solvent, a plasticizer, a diluent, or a combination of any two or more thereof and/or photo-hardenable black microcapsules 108.

### The Under-Layer

In some embodiments, the microcapsule imaging systems according to the present disclosure include an under-layer 102. The under-layer may serve as a primer layer between the first substrate and the imaging layer, or as an adhesive or tie layer to bond the photosensitive imaging layer to the first substrate. In some embodiments, the under-layer is overlaid on to one surface of a first substrate. In some embodiments, the under-layer is a primer layer. In some embodiments, the under-layer is an adhesive layer or a tie layer configured to couple two other layers to each other.

Pressure-Sensitive Microcapsules Containing Solvents, Plasticizers, and/or Diluents

In some embodiments, the under-layer may include one or more pressure-sensitive microcapsules 107 comprising a solvent, a plasticizer, a diluent, or a combination of any two or more thereof. In some embodiments, the solvent or a diluent is a solvent or a diluent for the leuco-dye in the one or more photosensitive microcapsules in the imaging layer, or a plasticizer for the leuco-dye developer. In some embodiments, the one or more pressure-sensitive microcapsules comprising the solvent, plasticizer, or diluent is non-photosensitive, that is, the core is neither softened nor hardened by actinic irradiation. In some embodiments, the pressure-sensitive microcapsules are photosensitive, in which the core is either softened or hardened by actinic irradiation. In some embodiments, the under-layer comprises the one or more pressure-sensitive microcapsules comprising a solvent, plasticizer, or diluent for the leuco-dye developer, alone or in combination with other microcapsules. In some embodiments, the solvent, plasticizer, or diluent comprises a reactive functional group such as epoxide that can react with the leuco-dye developer.

In some embodiments, the under-layer comprises one or more microcapsules comprising one or more of a solvent, plasticizer, or diluent at a concentration, measured by dry weight relative to the total dry weight of the under-layer, of at least about 1 wt. %, at least about 2 wt. %, at least about 3 wt. %, at least about 4 wt. %, at least about 5 wt. %, at least about 6 wt. %, at least about 7 wt. %, at least about 8 wt. %, at least about 9 wt. %, at least about 10 wt. %, at least about 11 wt. %, at least about 12 wt. %, at least about 13 wt. %, at least about 14 wt. %, at least about 15 wt. %, at least about 16 wt. %, at least about 17 wt. %, at least about 18 wt. %, at least about 19 wt. %, at least about 20 wt. %, at least about 25 wt. %, at least about 30 wt. %, or any range or value therein between. In some embodiments, the under-layer comprises one or more microcapsules comprising a solvent, plasticizer, or diluent at a concentration, measured by dry weight relative to the total dry weight of the under-layer, of less than about 80 wt. %, less than about 75 wt. %, less than about 70 wt. %, less than about 60 wt. %, less than about 50 wt. %, less than about 45 wt. %, less than about 40 wt. %, less than about 35 wt. %, less than about 30 wt. %, less than about 25 wt. %, less than about 20 wt. %, less than about 15 wt. %, less than about 10 wt. % or any range or value therein between.

In some embodiments, the solvent, plasticizer, or diluent includes, but is not limited to, vegetable oils, adipates, phthalates, dihydroxyalkanes, alkyl phosphates, ethers or esters of ethylene glycol, propylene glycol, glycerol, trimethylol propane, pentaerythritol, and their epoxided (epoxidized) derivatives, or a combination of any two of more thereof. In some embodiments, the epoxide compound comprises two or more epoxide moieties. In some embodiments, the diluent comprises a di-epoxide or tri-epoxide compound. In some embodiments, the epoxide compound comprises at least one selected from the group consisting of triglycidyl trimethylolpropane (TMPTGE); epoxided oils including epoxided soybean oil; epoxided castor oil; epoxided linseed oil; epoxided palm oil, dicyclopentadiene diepoxide; cycloaliphatic diepoxide; 3,4-epoxycyclohexylmethyl-3,4-epoxycyclohexanecarboxylate; and 1,2-cyclohexanedicarboxylic acid diglycidyl ester.

In some embodiments, the epoxide groups are not photopolymerizable by the radical-type photoinitiators which may be present in the microcapsules. In some embodiments, the epoxide compounds are configured to react with Lewis acids, phenol groups, or carboxylic groups, and/or the metal complexes, particularly zinc complexes, thereof. Thus, upon pressure development of the exposed image sheet, the epoxides released from the ruptured microcapsules will react and crosslink with the Lewis acid, phenol, or carboxylic acid group of the leuco-dye developers.

In some embodiments, the one or more solvent, plasticizer, and diluent are present in the pressure-sensitive microcapsules at a concentration, by weight, relative to the total weight of the internal phase, of no greater than about 40 wt. %, no greater than about 35 wt. %, no greater than about 30 wt. %, no greater than about 25 wt. %, no greater than about 20 wt. %, no greater than about 19 wt. %, no greater than about 18 wt. %, no greater than about 17 wt. %, no greater than about 16 wt. %, no greater than about 15 wt. %, no greater than about 14 wt. %, no greater than about 13 wt. %, no greater than about 12 wt. %, no greater than about 11 wt. %, no greater than about 10 wt. %, no greater than about 9 wt. %, no greater than about 8 wt. %, no greater than about 7 wt. %, no greater than about 6 wt. %, no greater than about 5 wt. %, no greater than about 4 wt. %, no greater than about 3 wt. %, no greater than about 2 wt. %, no greater than about 1 wt. %, or any range or value therein between. In some embodiments, the diluent is present at a concentration of about 3 wt. % to about 20 wt. %, relative to a total weight of the microcapsule. In some embodiments, the diluent is present at a concentration of about 3 wt. % to about 10 wt. %, relative to a total weight of the pressure-sensitive microcapsules.

In some embodiments, the solvent, plasticizer, or diluent has a water solubility of less than or equal to about 5 wt. %. In some embodiments, the solvent, plasticizer, or diluent has a water solubility of less than or equal to about 1 wt. %. The diluents or solvents for the leuco-dyes having a higher boiling point reduces the risk of premature evaporation during storage or transportation. Accordingly the diluents or solvents may have a boiling point of greater than about 100° C., greater than about 120° C., greater than about 150° C., greater than about 170° C., greater than about 200° C., and any range within these values. In some embodiments, the solvent, plasticizer, or diluent has a boiling point greater than about 150° C. In some embodiments, the solvent or diluent has a boiling point greater than about 200° C. A diluent or solvent of low viscosity is highly desirable to facilitate its diffusion to the developer layer and the rate of color development. In some embodiments, the solvent or diluent has a viscosity of less than or equal to about 600 cps at 25° C., determined using a Brookfield viscometer at 100 rpm. In some embodiments, the solvent or diluent has a viscosity of less than about 500 cps, less than about 400 cps, less than about 300 cps, less than about 200 cps, or less than about 100 cps at 25° C., determined using a Brookfield viscometer at 100 rpm. In some embodiments, the solvent or diluent has a viscosity less than 600 cps. In some embodiments, the solvent or diluent has a viscosity less than 150 cps.

### Photo-Hardenable Black Microcapsules

In some embodiments, the under-layer 102 may additionally or alternatively include one or more photo-hardenable black microcapsules 108 comprising a black leuco-dye or a leuco-dye system. In some embodiments, the under-layer comprises both the one or more photo-hardenable black microcapsules and one or more pressure-sensitive microcapsules comprising a solvent, plasticizer, or diluent for the leuco-dye developer. In some embodiments, the under-layer comprises only the one or more photo-hardenable black microcapsules. In some embodiments, the one or more photo-hardenable black microcapsules comprise a photo-polymerizable or photo-crosslinkable multifunctional monomer or oligomer and a black leuco-dye or a black leuco-dye system. The black leuco-dye system may include a combination of a black leuco-dye and a mixture of leuco-dyes (e.g., cyan, magenta, and yellow) fine-tuned to make the color more-like true black after development. In some embodiments, the black leuco-dye system comprises a mixture of two or more leuco-dyes. In some embodiments, the two or more leuco-dyes are selected from a black leuco-dye, a cyan leuco-dye, a magenta leuco-dye, a yellow leuco-dye, a red leuco-dye, a green leuco-dye, and a blue-leuco dye. In some embodiments, the black leuco-dye system comprises a black leuco-dye, and one or more leuco-dyes are selected from a cyan leuco-dye, a magenta leuco-dye, a yellow leuco-dye, a red leuco-dye, a green leuco-dye, and a blue-leuco dye.

In some embodiments, the photo-hardenable black microcapsule comprises the black leuco-dye or a black leuco-dye system at a concentration, relative to the total weight of the photo-hardenable black microcapsule, of about 0.1 wt. % to about 50 wt. %, about 1 wt. % to about 30 wt. %, or about 3 wt. % to about 20 wt. %, or any range or value therein. In some embodiments, the photo-hardenable black microcapsule comprises the black leuco-dye or a black leuco-dye system at a concentration, relative to the total weight of the photo-hardenable black microcapsule, of greater than or equal to about 0.1 wt. %, greater than or equal to about 0.2 wt. %, greater than or equal to about 0.3 wt. %, greater than or equal to about 0.4 wt. %, greater than or equal to about 0.5 wt. %, greater than or equal to about 0.6 wt. %, greater than or equal to about 0.7 wt. %, greater than or equal to about 0.8 wt. %, greater than or equal to about 0.9 wt. %, greater than or equal to about 1 wt. %, greater than or equal to about 2 wt. %, greater than or equal to about 3 wt. %, greater than or equal to about 4 wt. %, greater than or equal to about 5 wt. %, greater than or equal to about 6 wt. %, greater than or equal to about 7 wt. %, greater than or equal to about 8 wt. %, greater than or equal to about 9 wt. %, greater than or equal to about 10 wt. %, greater than or equal to about 15 wt. %, greater than or equal to about 20 wt. %, greater than or equal to about 25 wt. %, or any range or value therein. In some embodiments, the photo-hardenable black microcapsule comprises the black leuco-dye or a black leuco-dye system at a concentration, relative to the total weight of the photo-hardenable black microcapsule, of less than equal to about 60 wt. %, less than or equal to about 55 wt. %, less than or equal to about 50 wt. %, less than or equal to about 45 wt. %, less than or equal to about 40 wt. %, less than or equal to about 35 wt. %, less than or equal to about 30 wt. %, less than or equal to about 25 wt. %, less than or equal to about 20 wt. %, less than or equal to about 15 wt. %, less than or equal to about 10 wt. %, or any range or value therein.

In some embodiments, the photo-hardenable black microcapsule comprises one or more photoinitiators, one or more photo-polymerizable or photo-crosslinkable multifunctional monomers or oligomers, and a black leuco-dye or black leuco-dye system. In some embodiments, the photo-hardenable black microcapsule comprises one or more photoinitiators, one or more multifunctional monomers, and a black leuco-dye or black leuco-dye system. In some embodiments, the photo-hardenable black microcapsule comprises one or more photoinitiators, one or more multifunctional acrylate monomer, and a black leuco-dye or black leuco-dye system.

### Photoinitiators

In some embodiments, the photo-hardenable black microcapsule further comprises one or more photoinitiators. In some embodiments, the one or more photoinitiators comprises one or more borate initiators of the general structure:

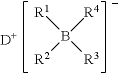

wherein D⁺ is a cationic chromophore, such as a cyanine, squaraine (e.g., squarylium), thiopyrylium, or triarylmethane. In some embodiments, R¹, R², R³, and R⁴ are each independently a substituted or unsubstituted alkyl, arylalkyl, or aryl group. In some embodiments, R¹ is an alkyl or arylalkyl group, and R², R³, and R⁴ are aryl groups. In some embodiments, the one or more photoinitiators comprise one or more of ketocoumarins, benzophenones, thioxanthones, and Norrish Type I, II and III photoinitiators, and combinations thereof. In some embodiments, the photoinitiator is a visible light-sensitive ketocoumarin, cyanine borate or semi-cyanine borate. In some embodiments, the photoinitiator is IR or UV sensitive.

In some embodiments, the one or more photoinitiators are present at a concentration, by weight, relative to the total weight of the internal phase, of greater than or equal to about 0.01 wt. %, greater than or equal to about 0.02 wt. %, greater than or equal to about 0.03 wt. %, greater than or equal to about 0.04 wt. %, greater than or equal to about 0.05 wt. %, greater than or equal to about 0.1 wt. %, greater than or equal to about 0.2 wt. %, greater than or equal to about 0.3 wt. %, greater than or equal to about 0.4 wt. %, greater than or equal to about 0.5 wt. %, greater than or equal to about 1.0 wt. %, greater than or equal to about 2.0 wt. %, greater than or equal to about 3.0 wt. %, greater than or equal to about 4.0 wt. %, greater than or equal to about 5.0 wt. %, greater than or equal to about 10.0 wt. %, or any range or value therein between. In some embodiments, the one or more photoinitiators are present in the internal phase at a concentration, by weight, relative to the total weight of the internal phase, of less than or equal to about 10.0 wt. %, less than or equal to about 5.0 wt. %, less than or equal to about 4.0 wt. %, less than or equal to about 3.0 wt. %, less than or equal to about 2.0 wt. %, less than or equal to about 1.0 wt. %, less than or equal to about 0.5 wt. %, less than or equal to about 0.4 wt. %, less than or equal to about 0.3 wt. %, less than or equal to about 0.2 wt. %, less than or equal to about 0.1 wt. %, less than or equal to about 0.05 wt. %, less than or equal to about 0.04 wt. %, less than or equal to about 0.03 wt. %, less than or equal to about 0.02 wt. %, less than or equal to about 0.01 wt. %, or any range or value therein between. In some embodiments, the one or more photoinitiators are present in the internal phase at a concentration, by weight, relative to the total weight of the internal phase, of about 0.01 wt. % to about 10.0 wt. %, about 0.01 wt. % to about 5.0 wt. %, about 0.01 wt. % to about 1.0 wt. %, about 0.01 wt. % to about 0.5 wt. %, about 0.01 wt. % to about 0.1 wt. %, about 0.01 wt. % to about 0.05 wt. %, about 0.05 wt. % to about 10.0 wt. %, about 0.1 wt. % to about 10.0 wt. %, about 0.1 wt. % to about 10.0 wt. %, about 0.5 wt. % to about 10.0 wt. %, about 1.0 wt. % to about 10.0 wt. %, about 5.0 wt. % to about 10.0 wt. %, about 0.05 wt. % to about 5.0 wt. %, about 0.1 wt. % to about 1.0 wt. %, or any range or value therein.

### Photo-Polymerizable or Photo-Crosslinkable Multifunctional Monomer or Oligomer

In some embodiments, the photo-hardenable black microcapsule comprises a multifunctional monomer or oligomer. In some embodiments, the monomers or oligomers are polymerizable or crosslinkable. In some embodiments, the monomers or oligomers are photo-hardenable. In some embodiments, the monomer or oligomer is selected from multifunctional acrylates and methacrylates, multifunctional vinyl ethers, multifunctional allyls or vinylbenzenes, and their oligomers, dendrimers or blends, and combinations thereof. In some embodiments, the multifunctional photo-polymerizable monomer or oligomer in the photosensitive microcapsules is selected from the group consisting of multifunctional acrylates, and their oligomers, dendrimers or blends thereof. Illustrative monomers and oligomers include, but are not limited to, pentaerythritol triacrylate (PETA-3), pentaerythritol tetra-acrylate (PETA-4), dipentaerythritol hexaacrylate (DPHA), dipentaerythritol pentaacrylate (DPPA), trimethylolpropane triacrylate (TMPTA), tris(2-hydroxyethyl) isocyanurate triacrylate, 1,2,4-butane triol trimethacrylate, 1,6-hexanediol diacrylate (HDDA), tripropylene glycol diacrylate (TPGDA), and neopentyl glycol diacrylate (NPGDA), 1,4-cyclohexanediol diacrylate, 1,4-benzenediol dimethacrylate, diethylene triamine tris-methacrylamide, vinyl esters (e.g., divinyl succinate), divinyl adipate, divinyl phthalate, divinyl terephthalate, divinylbenzene, or any combination thereof.

In some embodiments, the photo-hardenable black microcapsule further comprises one or more multifunctional acrylate monomers. Multifunctional acrylates are suitable due to their superior photospeed, compatibility with leuco dyes and developers, and outdoor weatherability. Suitable multifunctional acrylate monomers may include, but are not limited to, pentaerythritol triacrylate (PETA-3), pentaerythritol tetra-acrylate (PETA-4), dipentaerythritol hexaacrylate (DPHA), dipentaerythritol pentaacrylate (DPPA), trimethylolpropane triacrylate (TMPTA), 1,6-hexanediol diacrylate (HDDA), tripropylene glycol diacrylate (TPGDA), and neopentyl glycol diacrylate (NPGDA), or a combination of any two or more thereof.

In some embodiments, the one or more monomers or oligomers are present in the internal phase at a concentration by weight, relative to the total weight of the photo-hardenable black microcapsule, of no greater than about 90 wt. %, no greater than about 85 wt. %, no greater than about 80 wt. %, no greater than about 75 wt. %, no greater than about 70 wt. %, no greater than about 65 wt. %, no greater than about 60 wt. %, no greater than about 55 wt. %, no greater than about 50 wt. %, no greater than about 45 wt. %, no greater than about 40 wt. %, no greater than about 35 wt. %, no greater than about 30 wt. %, or any range or value therein between. In some embodiments, the one or more monomers or oligomers are present in the photo-hardenable black microcapsule at a concentration by weight, relative to the total weight of the internal phase, of about 40 wt. % to about 90 wt. %, about 50 wt. % to about 85 wt. %, or about 60 wt. % to about 80 wt. %.

### The Imaging Layer

The imaging layer 103 may be positioned between the under-layer and the developer layer. The imaging layer overlying the under-layer may include photosensitive microcapsules 106, which comprise a polymeric shell and a core (or internal phase) encapsulated therein. The internal phase comprises a leuco-dye, which imparts color to the microcapsule imaging system (e.g., sheet) upon release under pressure and/or simultaneous or subsequent exposure to heat, certain pH conditions, reactive chemical species, or a developer. Upon release from the microcapsule, the leuco-dye undergoes a chemical transformation, transitioning from a colorless state to a color state (e.g., yellow, magenta, cyan, or black).

The photosensitive microcapsules 106 may be photo-hardenable, photo-crosslinkable, or photo-polymerizable. In addition to the leuco-dye, the internal phase of the photosensitive microcapsules may further comprise one or more photoinitiators, one or more multifunctional monomers or oligomers, and optionally one or more non-photo-polymerizable reactive diluents. In some embodiments, the photosensitive microcapsules may comprise a polymeric shell and a light-sensitive core which may be photo-hardened by polymerizing or crosslinking the monomers/oligomers included therein. In some embodiments, the core or internal phase comprises a leuco-dye, a photoinitiator or sensitizer, and a photohardenable, polymerizable, or crosslinkable monomer or oligomer.

In some embodiments, the core or internal phase comprises a leuco-dye. In some embodiments, the leuco-dye is one or more of a yellow, cyan, magenta, or black leuco dye. By way of non-limiting example, a representative magenta leuco dye may include PERGASCRIPT® Red I6B (CAS: 50292-95-0, Synamedia-chem); COPIKEM 35 (CAS: 50292-91-6), Blue I-2G and Blue-63 from BASF, Blue 220, Blue 203, Red 500, Red 40 or Black 305 from Yamada, JYDY-1, JYDR-2, JYDR-3, JYDB-1, or JYDB-2 from WuXi Jiayida New Materials, Red-16, O-C6, or O-C8 from Synmedia Chemicals, or ODB-2 from Anyang General Chemicals. Additional suitable examples of leuco dyes are disclosed in, e.g., CHEMISTRY AND APPLICATIONS OF LEUCO DYES (R. Muthyala ed., 1997), which is hereby incorporated by reference. Suitable black leuco-dyes include, but are not limited to, ODB-2 from Weifang Dayoo Biochemical China, and Black-400, S-205 and Black 305 from Yamada Chemical, Japan. In another embodiment, the black leuco-dye system is a mixture of leuco-dyes including, for examples, cyan, magenta, and yellow leuco-dyes.

In some embodiments, the leuco dye is present in the internal phase at a concentration, by weight, relative to the total weight of the internal phase, of at least about 1 wt. %, at least about 2 wt. %, at least about 3 wt. %, at least about 4 wt. %, at least about 5 wt. %, at least about 6 wt. %, at least about 7 wt. %, at least about 8 wt. %, at least about 9 wt. %, at least about 10 wt. %, at least about 11 wt. %, at least about 12 wt. %, at least about 13 wt. %, at least about 14 wt. %, at least about 15 wt. %, at least about 16 wt. %, at least about 17 wt. %, at least about 18 wt. %, at least about 19 wt. %, at least about 20 wt. %, at least about 25 wt. %, at least about 30 wt. %, at least about 35 wt. %, at least about 40 wt. %, at least about 45 wt. %, at least about 50 wt. %, or any range or value therein between. In some embodiments, the leuco dye is present in the internal phase at a concentration, by weight, relative to the total weight of the internal phase, of no greater than about 50 wt. %, no greater than about 45 wt. %, no greater than about 40 wt. %, no greater than about 35 wt. %, no greater than about 30 wt. %, no greater than about 25 wt. %, or any range or value therein between. In some embodiments, the leuco dye is present in the internal phase at a concentration, by weight, relative to the total weight of the internal phase, of about 1 wt. % to about 50 wt. %, about 5 wt. % to about 40 wt. %, or about 10 wt. % to about 30 wt. %.

In some embodiments, the core or internal phase comprises a multifunctional monomer or oligomer. In some embodiments, the monomers or oligomers are polymerizable or crosslinkable. In some embodiments, the monomers or oligomers are photo-hardenable. In some embodiments, the monomer or oligomer is selected from multifunctional acrylates and methacrylates, multifunctional vinyl ethers, multifunctional allyls or vinylbenzenes, and their oligomers, dendrimers or blends, and combinations thereof. In some embodiments, the monomers or oligomers comprise multifunctional acrylates, which are suitable due to their superior photospeed, compatibility with leuco dyes and developers, and outdoor weatherability. Illustrative monomers and oligomers include, but are not limited to, pentaerythritol triacrylate (PETA-3), pentaerythritol tetra-acrylate (PETA-4), dipentaerythritol hexaacrylate (DPHA), dipentaerythritol pentaacrylate (DPPA), trimethylolpropane triacrylate (TMPTA), tris(2-hydroxyethyl) isocyanurate triacrylate, 1,2,4-butane triol trimethacrylate, 1,6-hexanediol diacrylate (HDDA), tripropylene glycol diacrylate (TPGDA), and neopentyl glycol diacrylate (NPGDA), 1,4-cyclohexanediol diacrylate, 1,4-benzenediol dimethacrylate, diethylene triamine tris-methacrylamide, vinyl esters (e.g., divinyl succinate), divinyl adipate, divinyl phthalate, divinyl terephthalate, divinylbenzene, or any combination thereof.

In some embodiments, the one or more monomers or oligomers are present in the internal phase at a concentration by weight, relative to the total weight of the internal phase, of no greater than about 90 wt. %, no greater than about 85 wt. %, no greater than about 80 wt. %, no greater than about 75 wt. %, no greater than about 70 wt. %, no greater than about 65 wt. %, no greater than about 60 wt. %, no greater than about 55 wt. %, no greater than about 50 wt. %, no greater than about 45 wt. %, no greater than about 40 wt. %, no greater than about 35 wt. %, no greater than about 30 wt. %, or any range or value therein between. In some embodiments, the one or more monomers or oligomers are present in the internal phase at a concentration by weight, relative to the total weight of the internal phase, of about 40 wt. % to about 90 wt. %, about 50 wt. % to about 85 wt. %, or about 60 wt. % to about 80 wt. %.

In some embodiments, the core or internal phase comprises a photoinitiator. In some embodiments, the photoinitiator is selected from the group consisting of one or more borate initiators. Suitable photoinitiators and their amounts may be as described herein for the under-layer.

The imaging layer may comprise one or more types of microcapsules. For instance, the microcapsules may include one or more microcapsules which may be selectively sensitive to one or more of white light, UV light, near-IR light, red visible light, green visible light, or blue visible light. In some embodiments, the imaging layer may comprise red-sensitive microcapsules. In some embodiments, the imaging layer may comprise green-sensitive microcapsules. In some embodiments, the imaging layer may comprise blue-sensitive microcapsules. In some embodiments, the imaging layer may comprise red-sensitive, green-sensitive, and blue-sensitive microcapsules, in which case the microcapsule imaging sheet is considered a “full-color” or a “panchromatic” imaging sheet.

In some embodiments, the spectral sensitivity of the photo-hardenable black microcapsule of the under-layer is different from that of the photosensitive microcapsule in the imaging layer. In some embodiments, the photo-hardenable black microcapsule of the under-layer is sensitive to a wavelength differing from one or more of a plurality of the wavelengths used to expose the photosensitive microcapsules in the imaging layer. For example, in one embodiment, the black microcapsule is sensitive to one or two of the 11, 12, and 13 wavelengths (e.g., red, green, and blue light) used to expose the photosensitive microcapsules in the imaging layer. In some embodiments, the photo-hardenable black microcapsule is sensitive to a wavelength different from each of the wavelengths used to expose the photosensitive microcapsules in the imaging layer. Thus, in another embodiment, the black capsule is sensitive to a wavelength (14) different from each of the 11, 12, and 13 (e.g., red, green, and blue light) used to expose the photosensitive microcapsules in the imaging layer. In some embodiments, the photo-hardenable black capsule is sensitive to one or more of white light, ultra-violet (UV), infra-red (IR), near IR, or yellow light. In some embodiments, the photosensitive microcapsules in the imaging layer are sensitive to one or more of red visible light, green visible light, or blue visible light.

The imaging layer suitably may have a thickness of at least about 1 μm, at least about 2 μm, at least about 3 μm, at least about 4 μm, at least about 5 μm, at least about 6 μm, at least about 7 μm, at least about 8 μm, at least about 9 μm, at least about 10 μm, at least about 15 μm, at least about 20 μm, at least about 25 μm, at least about 30 μm, at least about 35 μm, at least about 40 μm, at least about 45 μm, at least about 50 μm, or any range or value therein. In some embodiments, the imaging layer has a thickness from about 1 μm to about 30 μm, about 2 μm to about 25 μm, about 5 μm to about 20 μm, or about 6 μm to about 18 μm, or any range or value therein. In some embodiments, the imaging layer has a thickness of from about 5 μm to about 12 μm, In some embodiments, the imaging layer has a thickness of from about 6 μm to about 18 μm.

### Developer

In some embodiments, the imaging system further comprises a developer. In some embodiments, the developer comprises a leuco-dye developer. In some embodiments, the imaging system further comprises a separate developer layer. In some embodiments, the separate developer layer is overlaid, overcoated, or laminated onto the imaging layer. Thus, the leuco-dye developer may be present in the same layer as the imaging layer or in a different layer from the imaging layer. In some embodiments, the leuco-dye developer may be present in the same layer as the imaging layer. In some embodiments, the photosensitive microcapsule imaging layer and the leuco-dye developer layer are pre-mixed and overlayed as a single layer on the under-layer. In some embodiments, the leuco-dye developer may be present in a different layer as the imaging layer. In some embodiments, the imaging system further comprises a leuco-dye developer layer overlying the photosensitive microcapsule imaging layer. In some embodiments, the developer may be included in the under-layer.

In some embodiments, imaging system according to the present technology includes a developer layer that is contact with the second substrate at one side. The developer layer may be placed in contact with the imaging layer on the other side by for example, lamination after being applied to the second substrate. In some embodiments, the developer layer may be disposed or overcoated onto the imaging layer and the resultant over-coated sheet is used as is without the second substrate. In some embodiments, the over-coated developer/imaging layer may be further over-coated with a durable protective coating or laminated with a second substrate, optionally with an additional adhesive layer. In some embodiments, the imaging layer may be disposed or overcoated onto the developer layer, and the resultant imaging/developer on a second substrate is laminated with the under-layer on a first substrate. In some embodiments, the composition of the developer layer may be pre-mixed with the composition of the imaging layer and coated as a single layer onto the under-layer.

Suitable developers may include, but are not limited to a Lewis acid, an acid clay, or one or more compounds comprising a phenol group or carboxylic acid group, or metal complexes thereof. In some embodiments, the developer layer comprises one or more leuco dye developers. By way of non-limiting example, the developers may comprise Lewis acids, silicic acids, salicylic acid, benzoic acid, oxalic acid, phthalic acid, and their derivatives, novolac resins, and their metal complexes, particularly zinc complexes, or blends, composites, copolymers including graft and block copolymers, or combinations thereof. In some embodiments, the leuco-dye developer is selected from the group consisting of Lewis acids, acid clay, phenolic resins, novolac resins, salicylic acid, oxalic acid, and their derivatives, metal complexes, copolymers, blends, or composites. Illustrative developer(s) may include, without limitation, acid clay, zinc 3,5-bis(alpha-methylbenzyl) salicylate (e.g., N-054-W, SANKO Co., Ltd.), zinc 3,5-di-t-butyl salicylate, zinc 3,5-dioctyl salicylate, HRJ 4542 (Schenectady Chemical and Sumitomo Chemical), or novolac resin developers such as RD9870, RD9870A, RD9880, RD9880U, RF-118, etc. (Xinxiang Richful Lube Additive Co., Ltd.). In some embodiments, the leuco-dye developer is a zincated derivative. In some embodiments, the developer is zinc 3, 5-bis (alpha-methylbenzyl) salicylate, zinc 3,5-dialkylsalicylate, or zinc salts of salicylate-encapped or grafted novolac resins.

In some embodiments, the developer layer comprises two layers: (a) a low-haze clear developer layer (Dc); and (b) a microporous translucent developer layer (Dp). In some embodiments, the Dp layer is deposited between the photosensitive imaging layer and the Dc developer layer. In some embodiments, the two developer layers are of the same chemical composition. In some embodiments, the two developer layers are of different chemical composition. In some embodiments, the Dc layer may be of the same chemical composition but different morphology as that of the Dp layer. In some embodiments, the Dc layer may comprise therein a leuco-dye developer concentration lower than that of the Dp layer to reduce the discoloration after aging while maintaining the color fastness of the developed images. In other embodiment, the low-haze Dc layer comprises a lower concentration of leuco-dye developers than that of the microporous Dp layer. The leuco-dye developer may be an amorphous or crystalline material. In another embodiment, the leuco-dye developer is a zincated salicylate or phenolic types of developers or their blends or copolymers. The Dc layer may comprise of 5-90 wt. %, preferably 10-50 wt. % of a developer. The Dp layer may comprise of 70-98 wt. %, preferably 80-95 wt. % of a leuco-dye developer. In some embodiments, the developer layers may comprise other additives such as binders, optical brighteners and/or UV absorbers.

The developer layer(s), when present, may have any suitable thickness. For instance, the developer layer may have a thickness of at least about 1 μm, at least about 2 μm, at least about 3 μm, at least about 4 μm, at least about 5 μm, at least about 6 μm, at least about 7 μm, at least about 8 μm, at least about 9 μm, at least about 10 μm, at least about 15 μm, at least about 20 μm, at least about 25 μm, at least about 30 μm, at least about 35 μm, at least about 40 μm, at least about 45 μm, at least about 50 μm, or any range or value therein. In some embodiments, the developer layer has a thickness from about 1 μm to about 30 μm, about 2 μm to about 20 μm, or about 3 μm to about 15 μm.

The developer may be present in the one or more developer layers or may be included in any other layer at a concentration by weight, relative to the dry weight of the developer layer, of greater than or equal to about 5 wt. %, greater than or equal to about 10 wt. %, greater than or equal to about 20 wt. %, greater than or equal to about 30 wt. %, greater or equal to 50 wt. %, greater than or equal to about 55 wt. %, greater than or equal to about 60 wt. %, greater than or equal to about 65 wt. %, greater than or equal to about 70 wt. %, greater than or equal to about 75 wt. %, greater than or equal to about 80 wt. %, greater than or equal to about 85 wt. %, greater than or equal to about 90 wt. %, greater than or equal to about 95 wt. %, greater than or equal to about 96 wt. %, greater than or equal to about 97 wt. %, greater than or equal to about 98 wt. %, greater than or equal to about 99 wt. %, or any range or value therein between. In some embodiments, the developer layer may comprise a polymeric binder and a filler, such as silica and TiO₂.

In some embodiments, the developer may be used with one or more additives such as binders, fillers, optical brighteners, and/or UV absorbers. In some embodiments, the developer layer may comprise a polymeric binder, particularly a latex binder. Suitable binders, may include, without limitation, acrylic products, including acrylic latexes (e.g., Joncryl® 95 by BASF, P-208M1, P-208M3, P-208M4 and P-208M6 from Chang Chun Group Crop.; Primal AC-261T from Dow; Hycar 2679 and 26138 from Lubrizol), carboxylated, styrene-acrylic copolymer emulsion (e.g., Hycar® 26-1199 from Lubrizol), styrene-acrylic copolymer emulsion Joncryl 352D, Joncryl 7168 and Joncryl 1686 from BASF, and the blends and combinations thereof. Other useful latex binders include, but are not limited to, ethylene-vinyl acetate latexes, styrene-butadiene latexes, polyurethane latexes, and their copolymers or blends. Suitable optical brighteners may include, without limitation, 4,4′-bis(2-sulfostyryl)-biphenyl disodium salt (e.g., Doubletex CBS-1), 2,5-Bis (5-tert-butyl-2-benzoxazolyl)thiophene, and 4,4′-Bis (2-benzoxazolyl) stilbene (DOUBLETEX OB-1) from Taiwan Doubletex Corporation, and Disodium 4,4′-Bis (2-Sulfonatostyryl) biphenyl (e.g., Tinopal CBS-X from BASF). Suitable UV absorbers may include, without limitation, triazine-based UV absorbers (e.g., Tinuvin 400DW, Tinuvin® 400, Tinuvin® 405, Tinuvin® 460, Tinuvin® 477, Tinuvin® 479 from BASF), and benzotriazole UV Absorbers (e.g., Tinuvin® 384-2, Tinuvin® 1130, Tinuvin® 900, Tinuvin® 928 from BASF). The amount of each additive can range from about 0% to about 20%, including from about 0.1% to about 10%, about 0.5% to about 5%, about 0.8% to about 4%, about 0.9% to about 3%, or about 1% to about 2%, of the total weight of the developer layer or any other layer to which the developer is added are added, or any range including and/or in-between any two of these values.

### First and Second Substrates

In some embodiments, the imaging system comprises a first substrate 101 and a second substrate 105. In some embodiments, the under-layer is overlaid on to one side of the first substrate. The first substrate may include, for example, any coated paper and/or its pigmented derivatives. In some embodiments, the first substrate is white or transparent. In some embodiments, the first substrate comprises at least one of a polyester (e.g., polyethylene terephthalate (“PET”), polyethylene naphthalate (“PEN”), etc.), a cellulose-based polymer (e.g., cellulose triacetate), a polycarbonate, a polyolefin including cyclic-polyolefin, or combinations, blends, composites, laminates, or copolymers thereof. By way of non-limiting example, the first substrate may be selected from commercially-available films including, but not limited to, HOSTAPHAN® polyester films (Mitsubishi Polyester Film), MELINEX® (DuPont Teijin Films™), and MYLAR® polyester films (DuPont Teijin Films™).

The second substrate, may be positioned or overlaying on the developer layer and/or the imaging layer. In some embodiments, the developer layer is coated onto a second substrate. The second substrate may include, for example, any optically clear substrate. In some embodiments, the second substrate comprises at least one of a polyester (e.g., polyethylene terephthalate (“PET”), polyethylene naphthalate (“PEN”), etc.), a cellulose-based polymer (e.g., cellulose triacetate), a polycarbonate, polyolefin including cyclic-polyolefin, or combinations, blends, composites, laminates, or copolymers thereof. By way of non-limiting example, the second substrate may comprise a commercially-available film such as HOSTAPHAN® polyester films (Mitsubishi Polyester Film), MELINEX® (DuPont Teijin Films™), and MYLAR® polyester films (DuPont Teijin Films™).

The substrate may have any suitable thickness. In some embodiments, the first substrate and the second substrate may separately have a thickness of about 3 μm, about 3.5 μm, about 4 μm, about 4.5 μm, about 5 μm, about 10 μm, about 20 μm, about 30 μm, about 40 μm, about 50 μm, about 60 μm, about 70 μm, about 80 μm, about 90 μm, about 100 μm, about 150 μm, about 200 μm, about 250 μm, about 300 μm, about 350 μm, about 400 μm, about 450 μm, about 500 μm, or any range or value therein between. In some embodiments, the thickness of the first substrate is from about 12 μm to about 200 μm, or about 25 μm to about 150 μm. In some embodiments, the thickness of the second substrate is from about 3.5 μm to about 150 μm, or about 10 μm to about 100 μm.

In some embodiments, at least one of the first (101) and the second substrates (105) is an opaque or white substrate. As used herein, the term “opaque” means having a total light transmittance (TLT) of less than 20%, less than 10%, less than 9%, less than 8%, less than 7%, less than 6%, less than 5%, less than 4%, less than 3%, less than 2%, or less than 1%, as measured according to ASTM D1003. The term “white substrate” means a substrate having a whiteness index of at least about 90%, at least about 92%, at least about 95%, at least about 96%, at least about 97%, at least about 98%, at least about 99%, at least about 99.5%, or greater, as measured according to ASTM E313-79. In some embodiments, the first substrate (101) has a whiteness index of higher than 97%, as measured by ASTM E313-79.

In some embodiments, the under-layer is coated or overlaid on an opaque substrate and the developer layer or the imaging layer on a clear substrate. In some embodiments, the incipient light passes through the (top) developer layer or the imaging layer and hardens the (bottom) microcapsules. After development, the leuco dye diffuses up to the developer layer and forms color images therein. The opposite configuration, with top under-layer and bottom developer layer or the imaging layer layers, may also be used. In some embodiments, the first substrate (101) is opaque. In some embodiments, the second substrate (105) is transparent.

One or more of the following benefits are provided by embodiments of the present technology. For example, the addition of the diluent/solvent microcapsules and/or the photosensitive black microcapsules into under-layer or primer layer provides significantly improved color density and color saturation without noticeable trade-off in the minimum color density (Dmin). Additionally, the mid-tone graininess and mottle can be substantially decreased, which results in significantly improved image uniformity. Not to be bound by theory, it is believed that the diluent, plasticizer, or solvent released during or after the pressure development from the microcapsules in the under-layer or primer layer, significantly improves the diffusion rate of the leuco dyes into the developer layer(s) as well as the subsequent rate of reaction between the developers and the leuco-dyes. The diluent/solvent also significantly improves the degree of dye mixing and film formation in the developer layer and resulted in a better image quality with less observable graininess and mottle. The photosensitive black microcapsules in the under-layer (primer layer) further improves the rendition of a better black image which is very difficult to achieve with a traditional subtractive cyan, magenta, and magenta imaging system, particularly with a monolayer full-color microcapsule imaging system. In one aspect, which may be combined with any other aspect or embodiment, the present disclosure relates to a method of improving one or more properties of image color saturation, rate of image development and the degree of dye mixing, particularly in the low color density areas that meet the needs for high-quality, portable applications.

The use of a non-photo-polymerizable reactive epoxidized diluent/plasticizer either in the photosensitive leuco-dye microcapsules in the imaging layer or in a separate non-photosensitive microcapsule, also in the imaging layer has been taught in US Publication No. 2023/0393459A1 by the same inventors to facilitate the development of the leuco-dyes and the mixing of the dyes. However, since the diluent/plasticizer microcapsules and the photosensitive leuco-dye microcapsules are in the same layer, the former can only be incorporated at the expense of the latter in the imaging layer of a fixed thickness. To incorporate meaningfully higher loading of diluent/plasticizer, a significantly thicker imaging layer comprising multiple stacks of photosensitive microcapsules will be needed, which tends to result in a lower photo-speed of the lower stacks of the photosensitive microcapsules due to the undesirable optical screening effect caused by the light absorption and/or scattering by the upper stacks of photosensitive microcapsules. As such, only a low amount of diluent/plasticizer may be loaded in the imaging layer without the trade-offs including a level-off or even decrease in the maximum color density (Dmax), a decrease in photo-speed, and/or a lower image resolution. In some embodiments, the presence of the diluent/plasticizer/solvent in a separate layer from the photosensitive imaging layer comprising leuco-dye microcapsules affords an improvement in the Dmax, rate of dye development (fresh Dmax), and image uniformity, particularly in mid-tone image areas without observable trade-offs in Dmax, photospeed and/or image resolution. In some embodiments, the presence of the photo-hardenable black microcapsule in a separate layer from the photosensitive dye microcapsules affords an improvement in color saturation and the rendition of a better black tone image. In some embodiments, the presence of both the diluent and the photo-hardenable black microcapsule in a separate layer from the photosensitive dye microcapsules affords an improvement in color saturation, Dmax, fresh Dmax, black tone rendition, and mid-tone image uniformity.

### Methods of Preparing an Imaging Sheet

In another aspect, the present technology relates to methods of preparing an imaging sheet, comprising contacting a first substrate with an under-layer to produce a microcapsule-coated first substrate, the under-layer comprising one or more pressure-sensitive microcapsules comprising a solvent, plasticizer, or diluent and/or one or more photo-hardenable black microcapsules according to any of the above-discussed embodiments. In some embodiments, the under-layer is over-coated with an imaging layer comprising microcapsules according to any of the above-discussed embodiments. In some embodiments, the imaging layer comprises one or more photosensitive microcapsules according to any of the above-discussed embodiments. In some embodiments, the imaging layer is optionally contacted with a developer layer, or the imaging layer is directly contacted with a second substrate. In some embodiments, the developer layer is contacted with a second substrate.

In some embodiments, the under-layer may comprise one or more solvent, plasticizer, or diluent microcapsule comprising a polymeric shell; and an internal phase comprising a solvent or a diluent for the leuco-dye in the one or more photosensitive microcapsules, or a plasticizer for the developer. In some embodiments, the microcapsules comprise solvent microcapsules, diluent microcapsules, plasticizer microcapsules or any combination thereof. In some embodiments, the under-layer may comprise one or more photo-hardenable black microcapsules. In some embodiments, the one or more photo-hardenable black microcapsules comprises a photo-polymerizable or photo-crosslinkable multifunctional monomer or oligomer and a black leuco-dye or a black leuco-dye system. In some embodiments, an imaging layer may include photosensitive microcapsules for a microcapsule imaging system, the photosensitive microcapsule comprising a leuco-dye and a multifunctional photo-polymerizable or crosslinkable monomer or oligomer. In some embodiments, the microcapsule may comprise a photosensitive microcapsule comprising polymeric shell; and an internal phase comprising a leuco dye; a photoinitiator; and a polymerizable or crosslinkable monomer or oligomer.

In some embodiments, the method of producing an imaging sheet includes contacting the under-layer and/or imaging layer-coated first substrate with a developer layer to produce a developer-coated first substrate. In some embodiments, the developer-coated first substrate is contacted with a second substrate to produce an imaging system or sheet. In some embodiments, the developer layer is coated onto a second substrate to produce a developer-coated second substrate before being placed into contact with the microcapsule-coated first substrate to produce an imaging sheet. In some embodiments, the developer-coated second substrate and the microcapsule-coated first substrate are contacted with one another, such that the developer layer contacts the imaging layer. In some embodiments, a primer may be positioned between the second substrate and the developer layer.

### Methods of Using Microcapsules and Imaging Sheets

In another aspect, which may be combined with any other aspect or embodiment, the present disclosure relates to methods of using microcapsules according to any of the above-discussed embodiments. In another aspect, which may be combined with any other aspect or embodiment, the present disclosure relates to methods of using imaging sheets according to any of the above-discussed embodiments.

For example, in some embodiments, a method of imaging or printing includes exposing an imaging sheet comprising a microcapsule according to any of the above-discussed embodiments to heat, pressure, or radiation, wherein the exposing is sufficient to selectively release leuco dye and/or non-photopolymerizable diluent configured to react with a leuco dye developer from the microcapsules, to produce an image.

In some embodiments, the present disclosure relates to methods of adjusting (e.g., so as to improve) one or more properties of an imaging sheet, including adding microcapsules of the present disclosure to an imaging sheet. In some embodiments, the one or more properties comprises one or more of Dmax; fresh Dmax; Dmax, t; Dₘᵢₙ; image resolution; image uniformity, black tone, temperature latitude; dynamic range; discoloration (yellowing) resistance; and edge sharpness.

For the purpose of clarity and a concise description, features may be described herein as part of the same or separate aspects or embodiments of the present technology. It will be appreciated by the skilled person that the scope of the present technology may include embodiments having combinations of all or some of the features described herein as part of the same or separate embodiments.

The invention will be explained in more detail in the following, non-limiting examples. The examples are provided to illustrate coating processes applicable to making the particles of the present technology. These examples are not intended to limit the scope of the present technology. All parts and percentages are by weight unless otherwise indicated.

### EXAMPLES

### Materials

Table 1

| Tradename | Ingredient |
|---|---|
| Acrysol TT-615 | HASE thickener from Dow Corp. |
| Aerosol OT | Sodium bis (2-ethylhexyl) sulfosuccinate from Cytec Corp. |
| Plurafac ® LF305 | Surfactant from BASF. |
| Silwet L-7001 | Silicone surfactant from Momentive Performance Materials |
| Silwet L-7604 | Silicone surfactant from Momentive Performance Materials |
| Joncryl 7124 | Acrylic latex from BASF. |
| Hycar 26-1199 | Acrylic latex from The Lubrizol Corporation |
| Hycar 26138 | Acrylic latex from The Lubrizol Corporation |
| Joncryl 95 | Acrylic latex from BASF. |
| BR-054 | Color developer from Sanko Corp. |
| IRGANOX 1035 | Antioxidant from BASF |
| CAB-O-SPERSE | Aqueous dispersion of fumed silica from Cabot Corp. |
| 1015A | |
| Poval ™ 05-88 | Polyvinyl alcohol from Kuraray Crop. |
| Poval ™ 44-88 | Polyvinyl alcohol from Kuraray Crop. |
| TAMOL 731DP | Hydrophobic copolymer dispersant from Dow Corp. |
| TiO2 dispersion | Aqueous TiO₂ dispersion from Taiwan Nanotechnology Corporation. |
| PCC dispersion | Aqueous CaCO₃ dispersion from Taiwan Nanotechnology Corp. |
| Eastman AQ ™ 55S | Sulfopolyester from Eastman Chemical |
| Tinuvin 400DW | Aqueous triazine-based UV absorber dispersion from BASF |
| Desmodur ® N 100 | Polyisocyanate from Covestro Corp. |
| LexFeel 21 | TMP based ester oil from Inolex Corp. |
| Zemac E60 | Ethylene maleic anhydride copolymer from Aurorium Corp. |
| Versa TL502 | Sulfonated polystyrene from Nouryon Corp. |
| XIRAN 1000P | Styrene maleic anhydride (SMA) copolymers from Aurorium Corp. |
| Cymel 385 | Methylated high imino melamine resin from Allnex Corp. |
| ABEX 18S | Surfactant from Solvay Corp. |

### Example 1—Preparation of Photosensitive Microcapsules

182.67 parts of a 10 wt. % aqueous solution of ZeMac E60, 69.59 parts of a 15 wt. % solution of XIRAN 1000P in DI water, 10.44 parts of a 10 wt. % solution of ABEX-18S in DI water, 156.58 parts of a 20 wt. % solution of Na₂SO₄ in DI water, 10.44 parts of a 20 wt. % solution of NaHSO₄ in DI water, and 614.12 parts of DI water were mixed thoroughly at 500 rpm. The pH was then adjusted to 8.0 to form an aqueous phase of 1043.84 parts. 600.00 parts of the internal (oil) phase as shown in Table 2 were emulsified into the 1043.84 parts of the aqueous phase in a dark room to form a pre-emulsion of the internal phase.

| | Example -1a | Example-1b | Example-1c | Example-1d |
|---|---|---|---|---|
| | Yellow | Magenta | Cyan | Black |
| | Capsule | Capsule | Capsule | Capsule |
| | (Blue- | (Green- | (Red- | (Red & Green |
| Ingredients (in parts) | sensitive) | sensitive) | sensitive) | sensitive) |
| TMPTA (Trimethylolpropane triacrylate) | 430.65 | 429.22 | 453.82 | 430.98 |
| DM186 (Acrylated Epoxidized Soybean Oil) | 22.68 | 22.59 | 23.89 | 22.45 |
| DIDMA (2,6-diisopropyl-N,N-dimethylaniline) | 13.60 | 13.55 | 9.55 | 13.47 |
| Irganox ® 1035 | 0.23 | 2.71 | 1.43 | 1.35 |
| Yellow Leuco Dye (Hexylfluorescein Dimethyl | 68.00 | 0.00 | 0.00 | 27.83 |
| Ether from Aether industries, India) | | | | |
| Yellow Leuco Dye (CAS: 144190-25-0 | 22.68 | 0.00 | 0.00 | 0.00 |
| from Synmedia-chem) | | | | |
| Magenta Leuco Dye (CAS: 50292-95-0 | 0.00 | 90.36 | 0.00 | 37.26 |
| from Synmedia-chem) | | | | |
| Cyan Leuco Dye (CAS: 114090-18-5 | 0.00 | 0.00 | 52.55 | 24.69 |
| from NAGASE) | | | | |
| Cyan Leuco Dye (CAS: 132467-74-4 | 0.00 | 0.00 | 9.55 | 0.00 |
| from Synmedia-chem) | | | | |
| Black Leuco Dye (CAS: 89331-94-2 | 0.00 | 0.68 | 0.96 | 0.45 |
| from Angene Chemical) | | | | |
| EMTBS (Ethoxy-mercaptobenzothiazole | 3.63 | 3.16 | 3.34 | 3.14 |
| disulfide) from Aether, India | | | | |
| Tetrabutylammonium (sec-Butyl) | 0.91 | 0.90 | 0.96 | 0.90 |
| triphenylborate | | | | |
| Blue-sensitive photoinitiator 3-Ethyl-2-[(1- | 1.36 | 0.00 | 0.00 | 0.00 |
| Ethyl-3,3-dimethyl-1,3-dihydro-2H-indol-2- | | | | |
| ylidene)-methyl]benzothiazolium (sec- | | | | |
| Butyl)triphenylborate | | | | |
| Green-sensitive photoinitiator 1-Heptyl-2- | 0.00 | 0.68 | 0.00 | 0.67 |
| [3-(1heptyl-3,3-dimethyl-1,3-dihydro-indol- | | | | |
| 2-ylidene)-propenyl]-3,3dimethyl-3H- | | | | |
| indolium(sec-Butyl)triphenylborate | | | | |
| Red-sensitive photoinitiator 1-Heptyl-2-15- | 0.00 | 0.00 | 0.96 | 0.90 |
| (1-heptyl-3,3-dimethyl-1,3-dihydro-2H- | | | | |
| indol-2-ylidene)-penta-1,3-dienyl]- | | | | |
| 3,3dimethyl-3H-indolium(n- | | | | |
| Butyl(triphenylborate)) | | | | |
| Desmodur ® N 100 | 36.26 | 36.14 | 42.99 | 35.91 |

The formed pre-emulsion was pumped through a 30 μm SPG membrane twice followed by an 8 μm SPG membrane twice. 9.91 parts of a 10 wt. % solution of Abex 18S in DI water were added to 1300.00 parts of the emulsion thus obtained and stirred at 500 rpm for 10 min. 66.04 parts of a 10 wt. % ZeMac E60 solution in DI water, 55.00 parts of a 7.5 wt. % XIRAN 1000P solution in DI water, and 7.12 parts of diethylene triamine (DETA) with the pH preadjusted to 8.0 by a 5% H₃PO₄ solution in DI water, were added to the emulsion. The pH of the resultant emulsion was adjusted to 8.0 and allowed to react at 25° C. for 15 h at 500 rpm. 181.11 parts of a 10.5 wt. % of VERSA TL502 in DI water were added to the emulsion and allowed to react at 40° C. for an hour. The pH of the emulsion was adjusted to 6.0 and a mixture of 97.50 parts of Cymel 385 and 195.00 parts of DI water was added and allowed to react at 40° C. and 700 rpm for 3 h, followed by 3 h at 70° C. to form a slurry of photosensitive microcapsules.

### Example 2: Preparation of Diluent/Solvent Microcapsules

An isophorone diisocyanate (IPDI)-castor oil (molar ratio=3.05:1) prepolymer was prepared at 25° C. for 40 min with 250 ppm of dibutyltin dilaurate (DBTDL) as the catalyst. 22.12 parts of the prepolymer thus prepared were mixed thoroughly with 552.88 parts of LexFeel 21 to form the internal phase. 175.06 parts of a 10 wt. % solution of ZeMac E60 in DI water, 66.69 parts of 15 wt. % of XIRAN 1000P solution in DI water, 15.01 parts of 10 wt. % of ABEX 18S solution in DI water, and 743.59 parts of DI water were mixed thoroughly at 500 rpm and the pH was adjusted to 8.0 to form the aqueous phase. The internal phase (575.00 parts) was emulsified in the aqueous phase (1000.35 parts) with gentle mixing, followed by pumping twice through a 30 mm SPG membrane and twice through an 8 mm SPG membrane to form an internal phase emulsion-1. 9.91 parts of a 10 wt. % solution of ABEX 18S in DI water was added to 1300.00 parts of the internal phase emulsion, and the mixture was stirred at 500 rpm for 10 min to form an internal phase emulsion-2.

66.04 parts of a 10 wt. % ZeMac E60 solution in DI water, 55.00 parts of a 7.5 wt. % XIRAN 1000P solution in DI water, and 4.75 parts of diethylene triamine (DETA) with the pH preadjusted to 8.0 by a 5% H₃PO₄ solution in DI water, were added to the internal phase emulsion-2. The pH of the resultant emulsion was adjusted to 8.0 and allowed to react at 25° C. for 15 hours at 500 rpm. 192.11 parts of a 9.9 wt. % Versa TL502 solution in DI water were added and the resultant slurry was allowed to react at 40° C. for an hour. 104.39 parts of an 18.2 wt. % solution of Na₂SO₄ was added and the pH was adjusted to 6.0. 97.50 parts of Cymel 385 and 97.5 parts of DI water were then added. The resultant mixture was allowed to react at 40° C. at 700 rpm for two hours, followed by 70° C. for 3 additional hours to obtain a slurry of microcapsules containing pressure-releasable LexFeel 21 as the internal phase. The LexFeel 21 microcapsule slurry was diluted to about 15 wt. % with DI water, and the pH was adjusted to 9. The diluted slurry was filtered with a 500-mesh sieve and centrifuged twice to remove the aqueous phase.

### Example 3: Particle Size Distribution Analysis

All of the microcapsules prepared in Examples 1 and 2 were purified by the dilution, filtration centrifuge procedure. The resultant microcapsules were analyzed for particle size distribution using a Laser Diffraction Particle Size Analyzer LA-906 from Horiba, and the particle size was summarized in Table 3.

### Table 3

| | | Particle size (D₅₀) | Particle size (D₅₀) |
|---|---|---|---|
| Example | Description | (as prepared) | (after purification) |
| Example-1a | Yellow Microcapsule | 6.80 mm | 6.62 mm |
| Example-1b | Magenta Microcapsule | 7.06 mm | 6.81 mm |
| Example-1c | Cyan Microcapsule | 7.03 mm | 6.76 mm |
| Example-1d | Black Microcapsule | 6.28 mm | 6.63 mm |
| Example-2 | Diluent/Solvent Microcapsule | 6.93 mm | 6.79 mm |

### Example 4: Preparation of The Developer Sheet

The developer layer comprises two layers, namely, a low-haze clear developer layer (Dc) and a microporous translucent developer layer (Dp). Further information regarding exemplary imaging systems containing two-layer developer structures is set forth in the co-pending application entitled “Improved Imaging Media with Dual Layer Developer Structure,” filed on the same date (TSW-014), the entire contents of which are incorporated herein by reference, including for the developer structures therein. The two layer developer structure not only reduced the printing power consumption, but also widened the manufacturing process window of the subsequent lamination process for the making of imaging media of a fast color development rate. Illustrative compositions for Dc (Example 3a) and Dp (Example 3b) are shown in Table 4.

### Table 4

| Example 3a, | | Example 3b, | |
|---|---|---|---|
| Clear Developer Layer (Dc) | | Microporous Developer Layer (Dp) | |
| Ingredients | Dry Parts | Ingredients | Dry Parts |
| Hycar 26138S | 86.50 | BR-054 Dispersion | 75.65 |
| Tinuvin 400DW Dispersion | 2.50 | IRGANOX 1035 Dispersion | 11.00 |
| CAB-O-SPERSE 1015A | 1.00 | Hycar 26-1199 | 9.00 |
| BR-054 Dispersion | 10.00 | Poval ™ 05-88 | 3.35 |
| | | Poval ™ 44-88 | 0.15 |
| | | Triton X-114 | 0.17 |
| | | Aerosol OT | 0.57 |
| | | Abex 18S | 0.11 |

The BR-054 and Irganox 1035 dispersions in the above compositions were dispersed by a sand mill using the grinding formulations as shown in Examples 3c and 3d in Table 5, with the solid content and pH controlled at about 35-40 wt % and about 5.5, respectively.

### Table 5

| Example 3c, | | Example 3d, | |
|---|---|---|---|
| BR-054 Dispersion | | Irganox 1035 Dispersion | |
| Grinding formulation | Dry Parts | Grinding formulation | Dry Parts |
| BR-054 dispersion as received | 100.00 | IRGANOX 1035 | 100.00 |
| (42.5 wt % solid) | | | |
| Poval ™ 05-88 | 3.00 | Poval ™ 05-88 | 5.00 |
| Aerosol OT | 0.50 | Aerosol OT | 0.50 |
| Trtion X114 | 0.15 | Trtion X114 | 0.50 |
| Abex 18S | 0.15 | | |

The Dc layer was coated on a 15 mm clear PET by a wire bar and dried in an 80° C. oven for 10 min with a target dry thickness of 4 mm. The Dp layer was then over-coated on the Dc layer by a wire bar and dried in an 80° C. oven for 10 min with a target dry thickness of 9 mm to obtain a developer sheet with a total thickness of about 28 mm.

### Example 5A: Preparation of the Under-Layer (Primer Layer)

The under-layer (primer layer) compositions as shown in Table 6 were coated on a 50 □m white PET (Melinex 339 from DuPont Teijin Film) by a wire bar and dried in an 80° C. oven for 10 min with a target dry thickness of 4 □m. Examples 4-2 to 4-5 comprising the photosensitive black microcapsules were prepared in a dark room.

### Table 6

TABLE 6

| Ingredients | Example | Example | Example | Example | Example | Example |
|---|---|---|---|---|---|---|
| (in dry parts) | 4-0 | 4-1 | 4-2 | 4-3 | 4-4 | 4-5 |
| LexFeel 21 | 0.00 | 50.00 | 40.00 | 30.00 | 20.00 | 0.00 |
| Microcapsule from | | | | | | |
| Example 2 | | | | | | |
| Black Microcapsule | 0.00 | 0.00 | 10.00 | 20.00 | 30.00 | 50.00 |
| from Example 1d | | | | | | |
| TiO₂ dispersion | 60.00 | 10.00 | | | | |
| PCC CaCO₃ | 10.00 | | | | | |
| Dispersion | | | | | | |

| | |
|---|---|
| Acrysol TT615 | 0.40 |
| Nipacide BIT 10W | 0.05 |
| Aerosol OT | 0.18 |
| Triton X114 | 0.03 |
| Tamol 731DP | 2.20 |
| Joncryl 95 | 27.09 |
| Silwet L7604 | 0.05 |

### Example 5B: Preparation of the Photosensitive Imaging Layer

The composition of the full-color photosensitive imaging layer as shown in Table 7 was over-coated on the under-layer (primer layer) as prepared in Example 4 in a dark room by a wire bar and dried in an 80° C. oven for 10 min with a target dry thickness of 8 mm. The total thickness of the photosensitive microcapsule sheets is about 62 mm.

### Table 7

| Ingredients | Dry Parts |
|---|---|
| Yellow Microcapsule from Example 1a | 33.17 |
| Magenta Microcapsule from Example 1b | 33.17 |
| Cyan Microcapsule from Example 1c | 33.17 |
| PCC CaCO₃ Dispersion | 2.00 |
| TiO₂ Dispersion | 3.75 |
| Acrysol TT-615 | 0.34 |
| Aerosol OT | 0.50 |
| Triton X114 | 0.01 |
| Plurafac ® LF305 | 0.30 |
| Tamol 731 DP | 5.00 |
| Silwet L-7001 | 0.20 |
| Silwet L-7604 | 0.20 |
| Joncryl 7124 | 10.00 |
| AQ55S | 8.00 |

### Example 6: Preparation of the Full-Color Imaging Media

The photosensitive microcapsule/primer sheets of Example 5 were laminated onto the developer sheet as prepared in Example 3 at 85° C. (Roller temperature), 0.368m/min (lamination speed), and 3.621Kgf/170 mm (pressure). The thus prepared imaging sheets were then laminated with a black sticker comprising of a 38 μm black pressure-sensitive adhesive and a 25 μm transparent PET release liner to form the full-color imaging media (Examples 5-0 to 5-5). The total thickness of the full-color imaging media is about 153 μm. All the procedures were conducted in a dark room.

The imaging media was exposed sequentially with red-, green- and blue LED light through a 800 dpi monochrome TFT-LCD mask of 256 levels of grey scale and developed with a high pressure roller at 80° C. at a roller speed of about 4.5 in/min. The optical density and color gamut of the developed image were evaluated with an exact from X-Rite, MI, USA. The results are shown in Table 8 wherein Dmax and Dmin are the maximum image density and minimum image density, respectively, and
fDmax is the fresh Dmax measured immediately after the pressure development;
cDmax is the Dmax measured after the developed media was further developed by a 80° C. calendaring process;
ADmax is the Dmax measured after the calendered imaging medium was conditioned in a 60° C. oven for an hour;
Mid-tone graininess and mottle were measured with a QEA test equipment (from Quality Engineering Associates, Inc., MA, USA) in the areas with an image density of about 50% of the cDmax;
Color Gamut was determined by the L* a* b* values of the Dmax and Dmin areas and is represented by the % sRGB achievable by the full-color imaging media.

### Table 8

TABLE 8

| Ingredients | | 6-0 | | | | | |
|---|---|---|---|---|---|---|---|
| (in dry parts) | | (Control) | 6-1 | 6-2 | 6-3 | 6-4 | 6-5 |
| LexFeel 21 | | 0.00 | 50.00 | 40.00 | 30.00 | 20.00 | 0.00 |
| Microcapsule from | | | | | | | |
| Example 2 | | | | | | | |
| Black Microcapsule | | 0.00 | 0.00 | 10.00 | 20.00 | 30.00 | 50.00 |
| from Example 1d | | | | | | | |
| TiO₂ dispersion | | 60.00 | 10.00 | | | | |
| Cyan | fDmax | 0.64 | 0.65 | 0.69 | 0.71 | 0.67 | 0.64 |
| | cDmax | 0.67 | 0.72 | 0.74 | 0.77 | 0.73 | 0.73 |
| | ADmax | 0.71 | 0.81 | 0.83 | 0.85 | 0.82 | 0.81 |
| Magenta | fDmax | 0.73 | 0.86 | 0.87 | 0.88 | 0.88 | 0.84 |
| | cDmax | 0.75 | 0.92 | 0.92 | 0.94 | 0.94 | 0.85 |
| | ADmax | 0.81 | 1.01 | 1.03 | 1.06 | 1.05 | 0.99 |
| Yellow | fDmax | 0.69 | 0.80 | 0.77 | 0.77 | 0.76 | 0.77 |
| | cDmax | 0.73 | 0.85 | 0.86 | 0.85 | 0.80 | 0.85 |
| | ADmax | 0.85 | 1.01 | 1.01 | 1.00 | 0.98 | 0.99 |
| Black | fDmax | 0.96 | 1.03 | 1.04 | 1.01 | 0.98 | 1.00 |
| | cDmax | 1.04 | 1.08 | 1.15 | 1.13 | 1.04 | 1.10 |
| | ADmax | 1.22 | 1.40 | 1.45 | 1.33 | 1.30 | 1.28 |
| Dmin | Fresh | 0.03 | 0.04 | 0.04 | 0.04 | 0.05 | 0.05 |
| | Calendered | 0.03 | 0.03 | 0.03 | 0.03 | 0.04 | 0.04 |
| | 60° C., 1 h | 0.03 | 0.04 | 0.04 | 0.04 | 0.04 | 0.03 |
| Color | Fresh | 16.20% | 20.60% | 20.30% | 19.50% | 17.60% | 17.80% |
| Gamut | Calendered | 18.70% | 23.40% | 25.20% | 24.60% | 21.60% | 22.70% |
| | 60° C., 1 h | 23.30% | 31.20% | 32.90% | 31.20% | 27.90% | 27.60% |

| | | | | | | |
|---|---|---|---|---|---|---|
| Mid-tone Graininess | 0.07 | 0.05 | 0.05 | 0.06 | 0.06 | 0.06 |
| Mid-tone Mottle | 0.05 | 0.03 | 0.03 | 0.03 | 0.03 | 0.04 |

As can be seen from Table 8 that as compared to the Control (Example 6-0), the addition of the diluent/solvent (LexFeel 21) microcapsules and/or the photosensitive black microcapsules into under-layer or primer layer (Examples 6-1 to 6-5) significantly improved color density and color saturation without noticeable trade-off in Dₘᵢₙ. The image uniformity was also significantly improved, as evident from the decreases in the mid-tone graininess and mottle.

While certain embodiments have been illustrated and described, it should be understood that changes and modifications can be made therein in accordance with ordinary skill in the art without departing from the technology in its broader aspects as defined in the following claims.

The present disclosure is not to be limited in terms of the particular embodiments described in this application. Many modifications and variations can be made without departing from its spirit and scope, as will be apparent to those skilled in the art. Functionally equivalent methods and compositions within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, compounds, compositions, or structures, which can of course vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

Other embodiments are set forth in the following claims.

1. An imaging system comprising:
a) an under-layer comprising one or more pressure-sensitive microcapsules, said one or more pressure-sensitive microcapsules comprising a solvent, plasticizer, or diluent;
b) an imaging layer overlying the under-layer and comprising one or more photosensitive microcapsules; said one or more photosensitive microcapsules comprising a leuco-dye, a photoinitiator, and a multifunctional photo-polymerizable or photocrosslinkable monomer or oligomer; and
c) a leuco-dye developer;
wherein the solvent or a diluent is a solvent or a diluent for the leuco-dye in the one or more photosensitive microcapsules, or a plasticizer for the leuco-dye developer.

2. The imaging system of claim 1, wherein the leuco-dye developer is present in the same layer as the imaging layer, or wherein the leuco-dye developer is present in a different layer from the imaging layer.

3. (canceled)

4. The imaging system of claim 1, wherein the one or more photosensitive microcapsules is photo-hardenable, photo-crosslinkable, or photo-polymerizable.

5. The imaging system of claim 1, wherein the one or more pressure-sensitive microcapsules comprising the solvent, plasticizer, or diluent is non-photosensitive or is photosensitive.

6. (canceled)

7. The imaging system of claim 1, wherein the solvent, plasticizer or diluent has a boiling point greater than about 150° C.

8. (canceled)

9. The imaging system of claim 1, wherein the solvent or diluent has a viscosity less than 600 cps.

10. (canceled)

11. The imaging system of claim 1, wherein the solvent, plasticizer or diluent is selected from the group consisting of vegetable oils, adipates, phthalates, dihydroxyalkanes, alkyl phosphates, ethers or esters of ethylene glycol, propylene glycol, glycerol, trimethylol propane, pentaerythritol, and their epoxidized derivatives, or a combination of any two of more thereof.

12. The imaging system of claim 1, wherein the leuco-dye developer is selected from the group consisting of Lewis acids, acid clay, phenolic resins, novolac resins, salicylic acid, oxalic acid, phthalic acid, and their derivatives, metal complexes, and copolymers, blends, or composites thereof.

13. The imaging system of claim 1, wherein the leuco-dye developer is a zincated derivative.

14. The imaging system of claim 1, wherein the under-layer is a primer layer, an adhesive layer or a tie layer.

15. (canceled)

16. The imaging system of claim 1, wherein the under-layer is overlaid on one surface of a first substrate.

17. The imaging system of claim 1, further comprising a second substrate with the photosensitive imaging layer and/or the leuco-dye developer layer deposited thereon.

18. An imaging system comprising:
a) an under-layer comprising one or more photo-hardenable black microcapsules, said one or more photo-hardenable black microcapsules comprising a photo-polymerizable or photo-crosslinkable multifunctional monomer or oligomer and a black leuco-dye or a leuco-dye system; and
b) an imaging layer overlying the under-layer and comprising one or more photosensitive microcapsules; said photosensitive microcapsules comprising a leuco-dye, a photoinitiator, and a multifunctional photo-polymerizable or crosslinkable monomer or oligomer.

19. The imaging system of claim 18, wherein the leuco-dye system comprises a mixture of two or more leuco-dyes; and wherein the two or more leuco-dyes are selected from a black leuco-dye, a cyan leuco-dye, a magenta leuco-dye, a yellow leuco-dye, a red leuco-dye, a green leuco-dye, and a blue-leuco dye.

20. (canceled)

21. The imaging system of claim 18, wherein the under-layer further comprises one or more pressure-sensitive microcapsules comprising a solvent, plasticizer, or a diluent for the leuco-dye.

22. The imaging system of claim 18, wherein the photo-hardenable black microcapsule comprises a photoinitiator, a multifunctional acrylate monomer, and a black leuco-dye or a leuco-dye system.

23. The imaging system of claim 18, wherein the spectral sensitivity of the photo-hardenable black microcapsule of the under-layer is different from that of the photosensitive microcapsule imaging layer.

24. (canceled)

25. The imaging system of claim 18, wherein the photo-hardenable black microcapsule is sensitive to a wavelength differing from each of a plurality of wavelengths used to expose the photosensitive microcapsules in the imaging layer.

26. The imaging system of claim 18, wherein the photo-hardenable black capsule is sensitive to white, ultra-violet, infra-red, near infra-red, or yellow light.

27. An imaging system comprising:
a) a first substrate having two sides;
b) an under-layer overlaying one side of the first substrate, the under-layer comprising one or more microcapsules;
c) a photosensitive microcapsule imaging layer overlying the under-layer and comprising one or more photosensitive microcapsules; said photosensitive microcapsules comprising a leuco-dye, a multifunctional photo-polymerizable or photocrosslinkable monomer or oligomer; and
d) a leuco-dye developer layer overlaying the photosensitive microcapsule imaging layer;
wherein the one or more microcapsules in the under-layer comprises at least one of:
(i) a solvent, plasticizer, or a diluent for the leuco-dye in the photosensitive microcapsule or the leuco-dye developer; or
(ii) a multifunctional photo-polymerizable or cross-linkable monomer or oligomer, a photoinitiator, and a black leuco-dye or a leuco-dye system.

28. The imaging system of claim 27, wherein the photosensitive microcapsule imaging layer and the leuco-dye developer layer are pre-mixed and overlayed as a single layer on the under-layer.

29. The imaging system of claim 28, further comprising a second substrate overlaying the developer layer or the imaging layer.

30. The imaging system of claim 27, wherein the developer layer comprises two layers: (a) a low-haze clear developer layer (Dc); and (b) a microporous translucent developer layer (Dp).

31. The imaging system of claim 27, wherein
(a) the multifunctional photo-polymerizable monomer or oligomer in the photosensitive microcapsules is selected from the group consisting of multifunctional acrylates, and their oligomers, dendrimers or blends thereof; or
(b) the multifunctional photo-polymerizable or cross-linkable monomer in the pressure-sensitive microcapsules is selected from the group consisting of multifunctional acrylates, and their oligomers, dendrimers or blends thereof.

32. (canceled)

33. The imaging system of claim 31, wherein the multifunctional acrylate is selected from the group consisting of pentaerythritol triacrylate (PETA-3), pentaerythritol tetra-acrylate (PETA-4), dipentaerythritol hexaacrylate (DPHA), dipentaerythritol pentaacrylate (DPPA), trimethylolpropane
